(19) United States
(12) Patent Application Publication
(10) Pub. No.: US 2026/0173980 A1
(43) Pub. Date: Jun. 18, 2026

(54) MOUNTING STRUCTURE AND METHOD FOR MANUFACTURING SAME

(71) Applicant: Panasonic Intellectual Property Management Co., Ltd., Osaka (JP)

(72) Inventors: KOHEI ISOI, Osaka (JP); KIYOKAZU ITOI, Osaka (JP); DAISUKE SAKURAI, Osaka (JP)

(21) Appl. No.: 19/408,463

(22) Filed: Dec. 4, 2025

(30) Foreign Application Priority Data
Dec. 12, 2024 (JP) 2024-217304

(51) Int. Cl. H10W 90/00; H10W 72/00; H10W 72/20; H10W 72/29; H10W 80/00

(52) U.S. Cl. CPC H10W 90/724; H10W 72/01215; H10W 72/222; H10W 72/234; H10W 72/252; H10W 72/255; H10W 72/29; H10W 80/334

(57) ABSTRACT

The mounting structure includes a first member including a first electrode pad and a metal bump disposed on a surface of the first electrode pad, and a second member disposed to face the first member and including a second electrode pad bonded to the metal bump, and a second insulating layer. An oxide film is formed on a surface of the metal bump. A metal bonding portion is formed between the metal bump and the second electrode pad, wherein at the metal bonding portion, metal constituting the metal bump and metal constituting the second electrode pad are metal-bonded. An oxide film bonding portion is formed between the oxide film and the second insulating layer, wherein at the oxide film bonding portion, the oxide film and the second insulating layer are bonded.

### BACKGROUND

### 1. Technical Field

The present disclosure relates to a mounting structure obtained by bonding a metal bump provided on a first member and a second electrode pad provided on a second member, and a method for manufacturing the mounting structure.

### 2. Description of the Related Art

In recent years, densities of semiconductor devices and the number of pins of electrode terminals have been increased, and a pitch of electrode terminals provided in the semiconductor devices and an area of the electrode terminals have been reduced. Flip-chip mounting is known as one of mounting techniques for mounting a narrow pitch terminal on a mount board of the semiconductor device.

In the flip-chip mounting, a protruding electrode formed on the electrode terminal of the semiconductor device such as a system LSI, a memory, or a CPU is pressed and heated against an electrode pad of the mount board such as a circuit board or a wiring board.

Many solder bumps are adopted for the protruding electrode formed on the electrode terminal. As a method for forming a solder bump on the electrode terminal in a protruding shape, for example, screen printing, dispensing, electrolytic plating, or the like is known. By these methods, solder is formed on the electrode terminal, and then the semiconductor device and the mount board are heated in a reflow furnace at a temperature equal to or higher than a melting point of the solder to bond the protruding electrode and the electrode pad.

However, since the solder is in a liquid phase state at the time of bonding, a short circuit between the terminals due to the solder is likely to occur as the pitch of the electrode terminals is reduced. Therefore, when a demand for reducing the pitch of the electrode terminals is severe, it is difficult to adopt the solder bump for the protruding electrode.

Thus, a method for adopting, for example, a columnar fine metal bump made of copper or the like in place of the solder bump as the electrode formed on the electrode terminal has been known. In this method, in a pressing and heating step at the time of flip-chip mounting, a tip end of the protruding electrode is plastically deformed and brought into close contact with the electrode pad, thereby bonding the protruding electrode to the electrode pad. According to this method, since the fine metal bump is not changed to the liquid phase state in the pressing and heating step at the time of flip-chip mounting, it is possible to prevent the short circuit between the terminals that occurs in the case of the solder bump.

For example, Patent Literature (PTL) 1 discloses a configuration in which the protruding electrode has a structure having a metal film on an outer peripheral portion of the columnar fine metal bump, thereby preventing the short circuit between the terminals.

PTL 1: Unexamined Japanese Patent Publication No. 2000-294585

### SUMMARY

In order to achieve the above object, a mounting structure according to an aspect of the present disclosure includes a first member and a second member. The first member includes a first electrode pad and a metal bump disposed on a surface of the first electrode pad. The second member is disposed to face the first member and includes a second electrode pad bonded to the metal bump, and a second insulating layer. An oxide film is formed on a surface of the metal bump. A metal bonding portion is formed between the metal bump and the second electrode pad, wherein at the metal bonding portion, metal constituting the metal bump and metal constituting the second electrode pad are metal-bonded. An oxide film bonding portion is formed between the oxide film and the second insulating layer, wherein at the oxide film bonding portion, the oxide film and the second insulating layer are bonded.

A method for manufacturing the mounting structure according to the aspect of the present disclosure includes a first pressurizing step, a first heating step, and a second pressurizing step. In the first pressurizing step, a load is applied between the first member and the second member in a state where the first member and the second member face each other, to form the metal bonding portion between the metal bump and the second electrode pad. In the first heating step, the first member and the second member are heated after performing the first pressurizing step, to increase a bonding area of the metal bonding portion. In the second pressurizing step, a load higher than the load in the first pressurizing step is applied between the first member and the second member, to form the oxide film bonding portion at least between the oxide film and the second insulating layer.

### BRIEF DESCRIPTION OF THE DRAWINGS

FIG. 1 is a schematic sectional view of a first main part of a mounting structure according to a first embodiment;

FIG. 2 is an enlarged view of a part of the mounting structure illustrated in FIG. 1;

FIG. 3 is a schematic plan view of a bonding surface between a metal bump and an electrode pad in the mounting structure illustrated in FIG. 2;

FIG. 4 is a schematic sectional view of a second main part of the mounting structure according to the first embodiment;

FIG. 5 is an enlarged view of a part of the mounting structure illustrated in FIG. 4;

FIG. 6 is a schematic plan view of the bonding surface between the metal bump and the electrode pad in the mounting structure illustrated in FIG. 5;

FIG. 7A is a schematic sectional view for explaining a method for manufacturing the mounting structure according to the first embodiment;

FIG. 7B is a schematic sectional view for explaining a step subsequent to FIG. 7A;

FIG. 7C is a schematic sectional view for explaining a step subsequent to FIG. 7B;

FIG. 7D is a schematic sectional view for explaining a step subsequent to FIG. 7C;

FIG. 7E is a schematic sectional view for explaining a step subsequent to FIG. 7D;

FIG. 8 is a diagram illustrating an example of temporal changes in temperature and load applied to the mounting structure in a manufacturing process;

FIG. 9A is a schematic plan view of the bonding surface between the metal bump and the electrode pad while performing a first pressurizing step;

FIG. 9B is a schematic plan view of the bonding surface between the metal bump and the electrode pad while performing a second pressurizing step;

FIG. 10 is a schematic sectional view of the second main part of the mounting structure according to a second embodiment;

FIG. 11 is an enlarged view of a part of the mounting structure illustrated in FIG. 10;

FIG. 12 is a schematic plan view of the bonding surface between the metal bump and the electrode pad in the mounting structure illustrated in FIG. 11;

FIG. 13A is a schematic sectional view for explaining the method for manufacturing the mounting structure according to the second embodiment;

FIG. 13B is a schematic sectional view for explaining a step subsequent to FIG. 13A;

FIG. 13C is a schematic sectional view for explaining a step subsequent to FIG. 13B;

FIG. 13D is a schematic sectional view for explaining a step subsequent to FIG. 13C; and

FIG. 13E is a schematic sectional view for explaining a step subsequent to FIG. 13D.

### DETAILED DESCRIPTIONS

When flip-chip mounting is performed, regardless of whether a solder bump or a fine metal bump is used, the bump may be shifted from a center of an electrode pad due to misalignment or the like at the time of mounting, and come into contact with an insulating layer outside the electrode pad, for example, silicon oxide or the like. In a semiconductor device, when a pitch of electrode terminals and an area of the electrode terminals described above are further reduced, it is considered that a rate of contact between such a bump and the insulating layer also increases.

However, since metal constituting the bump, for example, copper or the like and silicon oxide constituting the insulating layer are dissimilar materials, bonding strength cannot be secured, and a problem that the bonding strength is lowered occurs at a portion where the bump and the insulating layer are in contact with each other. In addition, when the number of portions where the bump and the insulating layer are in contact with each other increases or a total area of the portions increases, the bonding strength between the semiconductor device provided with the bump and a mount board provided with the electrode pad significantly decreases. In addition, not only in the case of the semiconductor device and the mount board, but also in the case of manufacturing a mounting structure with a first member provided with the bump and a second member provided with the electrode pad, the same problem occurs.

The present disclosure has been made in view of such a point, and an object of the present disclosure is to provide a mounting structure and a method for manufacturing the mounting structure capable of increasing tolerance of misalignment at the time of mounting and securing the bonding strength.

Hereinafter, embodiments of the present disclosure will be described with reference to the drawings. Note that the following description of preferred embodiments is merely exemplary in nature, and is not intended to limit the present disclosure, its application, or its use.

### First Embodiment

### Configuration of Mounting Structure

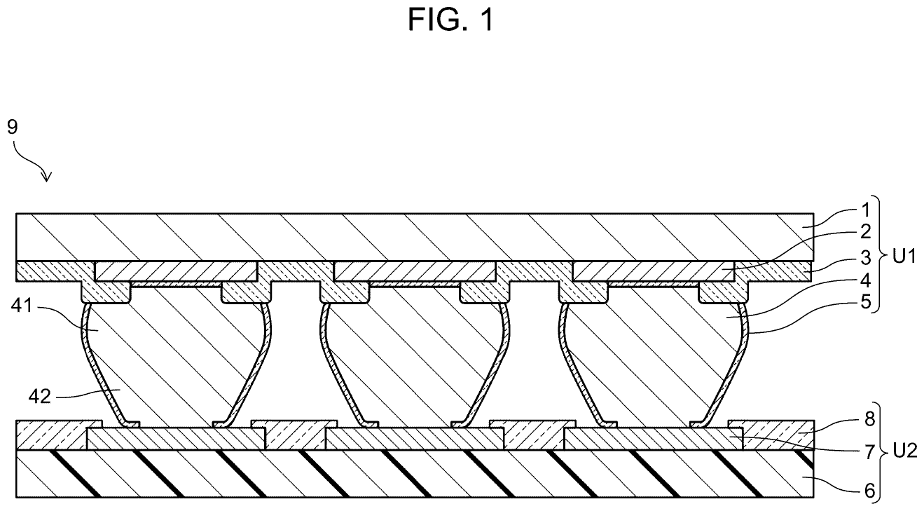

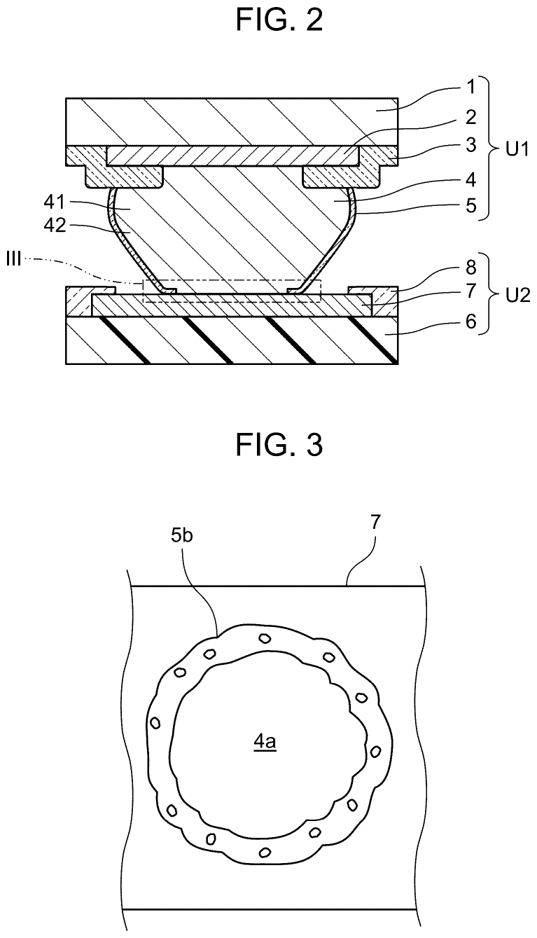

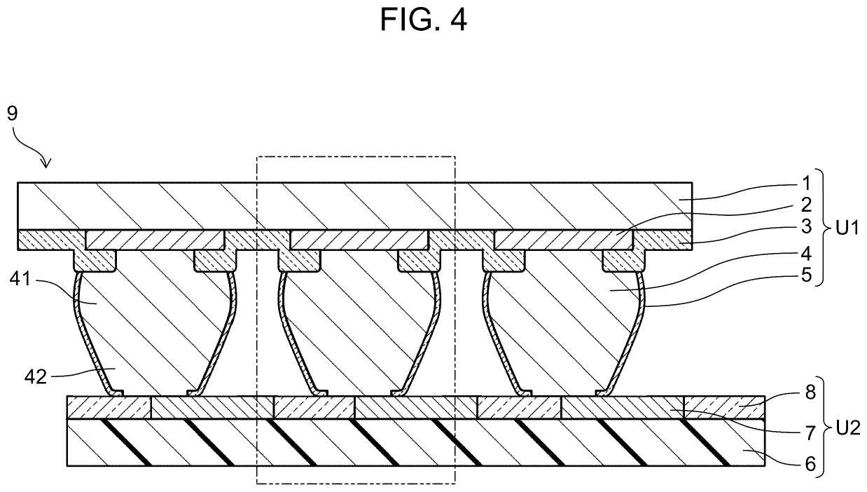

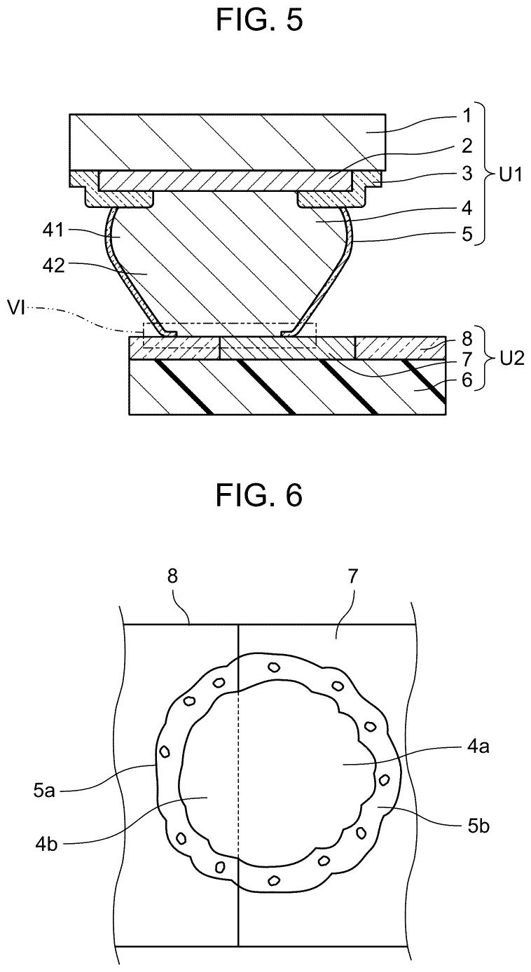

FIG. 1 is a schematic sectional view of a first main part of a mounting structure according to a first embodiment. FIG. 2 is an enlarged view of a part of the mounting structure illustrated in FIG. 1. FIG. 3 is a schematic plan view of a bonding surface between a metal bump and an electrode pad in the mounting structure illustrated in FIG. 2. FIG. 4 is a schematic sectional view of a second main part of the mounting structure according to the first embodiment. FIG. 5 is an enlarged view of a part of the mounting structure illustrated in FIG. 4. FIG. 6 is a schematic plan view of the bonding surface between the metal bump and the electrode pad in the mounting structure illustrated in FIG. 5. Note that, in the following description, a case where mounting structure 9 is viewed in a mode having a shape illustrated in FIGS. 1 and 4 will be referred to as a sectional view. Further, a stacking direction of first member U1 and second member U2 may be referred to as a vertical direction. In the vertical direction, a side on which first member U1 is disposed may be referred to as upper or upper side, and a side on which second member U2 is disposed may be referred to as lower or lower side.

As illustrated in FIGS. 1, 2, 4, and 5, mounting structure 9 is formed by mounting first member U1 and second member U2 disposed to face first member U1. First member U1 in the present embodiment has semiconductor device 1, first electrode pad 2, first insulating layer 3, and metal bump 4.

Semiconductor device 1 is, for example, a large scale integration (LSI). A main constituent material of semiconductor device 1 is, for example, silicon, gallium arsenide, gallium nitride, silicon carbide, indium gallium arsenide, gallium nitride, indium phosphorus, or the like. Note that the semiconductor device 1 may be a discrete device or a monolithic IC. Further, the semiconductor device 1 may be a transistor, a rectifier element, a sensor element, a light emitting element, a light receiving element, or the like.

A plurality of the first electrode pads 2 are provided in semiconductor device 1. First electrode pad 2 is made of metal, and a material thereof is, for example, any one of gold, copper, aluminum, aluminum silicon containing a predetermined amount of silicon, for example, 0.1% or more, an alloy of aluminum and copper, and tungsten.

The first insulating layer 3 is formed to cover a surface of semiconductor device 1 on which first electrode pad 2 is provided. Further, first insulating layer 3 covers a peripheral edge of first electrode pad 2. Note that first insulating layer 3 is open on a surface of first electrode pad 2, and most of the surface of first electrode pad 2 is not covered with first insulating layer 3 and is exposed. However, the first insulating layer 3 is not limited thereto, and an entire surface of first electrode pad 2 may not be covered with first insulating layer 3 and may be exposed.

Metal bump 4 is made of, for example, metal that is relatively easy to form oxides of, for example, copper, aluminum, titanium, tungsten, or the like. As illustrated in FIGS. 1, 2, 4, and 5, in a sectional view, metal bump 4 has a tapered shape in which a width of a portion in contact with second electrode pad 7 is narrower than a width of a portion in contact with first electrode pad 2. In other words, metal bump 4 has bottom portion 41 in contact with the surface of first electrode pad 2 and tip end 42 protruding from bottom portion 41 toward second electrode pad 7, and a diameter of bottom portion 41 is larger than that of tip end 42. However, shape of metal bump 4 is not particularly limited to shapes illustrated in FIGS. 1, 2, 4, and 5.

Although not illustrated, a barrier layer may be formed at an interface between first electrode pad 2 and metal bump 4. The barrier layer is formed by, for example, laminating one or more high melting point metals such as titanium, titanium nitride, and tungsten, and prevents, for example, metal constituting metal bump 4 from being excessively alloyed with first electrode pad 2.

Oxide film 5 is formed on a surface of metal bump 4 except for a bonding surface with first electrode pad 2 and a bonding surface with second electrode pad 7. Oxide film 5 is a metal oxide formed by oxidizing metal bump 4. A thickness of oxide film 5 is about 10 nm to 1000 nm, but is not particularly limited thereto, and may be any thickness that allows formation of an oxide film bonding portion 5a described later.

Second member U2 in the present embodiment has mount board 6, second electrode pad 7, and second insulating layer 8.

Mount board 6 is, for example, a wiring board made of an insulator such as a resin material or ceramic and having a plurality of the second electrode pads 7 formed on one surface thereof. Although not illustrated, wiring and land electrode electrically connected to each of the plurality of second electrode pads 7 are formed on the same surface as the surface on which second electrode pads 7 are formed. Note that the wiring and the land electrode not electrically connected to each of the second electrode pads 7 may be formed on the same surface. Further, mount board 6 may be a circuit board with an electronic component (not illustrated) mounted on the land electrode.

Further, a via penetrating mount board 6 in a thickness direction may be formed. In this case, an inside of the via is filled with a conductive metal, and one end of the via is connected to second electrode pad 7 or the wiring and the land electrode described above. An electrode pad (not illustrated) may be provided on a surface facing a surface on which the second electrode pad 7 is formed in the thickness direction. The other end of the via is connected to this electrode pad.

The plurality of second electrode pads 7 are provided on mount board 6. Second electrode pad 7 is made of metal, and a material thereof is, for example, the same as the material of first electrode pad 2.

Second insulating layer 8 is formed to cover a surface of mount board 6 on which second electrode pad 7 is provided. Further, second insulating layer 8 covers a peripheral edge of second electrode pad 7. Note that second insulating layer 8 is open on a surface of second electrode pad 7, and most of the surface of second electrode pad 7 is not covered with second insulating layer 8 and is exposed. However, the present invention is not limited thereto, and an entire surface of second electrode pad 7 may not be covered with second insulating layer 8 and may be exposed.

Second insulating layer 8 is made of an insulating material containing at least one of silicon oxide (SiOₓ (1<x≤2) and silicon nitride (Si₃N₄₋ₓ (0≤x<1)). Note that a material of first insulating layer 3 may be the same as or different from that of second insulating layer 8.

Metal bump 4 and second electrode pad 7 are bonded to each other on a surface where metal bump 4 and second electrode pad 7 are in contact with each other. As illustrated in FIGS. 1 to 3, a case is considered in which metal bump 4 is bonded to second electrode pad 7 without protruding from the surface of second electrode pad 7.

In this case, as illustrated in FIG. 3, metal bonding portion 4a and dissimilar material bonding portion 5b are formed on a bonding surface between metal bump 4 and second electrode pad 7. Note that a plurality of circles drawn in dissimilar material bonding portion 5b indicate voids formed inside dissimilar material bonding portion 5b. The voids are formed depending on surface roughness of metal bump 4 and second electrode pad 7.

Metal bonding portion 4a is a portion where the metal constituting metal bump 4 and metal constituting second electrode pad 7 are metal-bonded. In the present embodiment, both metal bump 4 and second electrode pad 7 are made of copper. Therefore, metal bonding portion 4a is a portion formed by metal-bonding copper to copper, that is, metals of the same kind.

On the other hand, composition of oxide film 5 is CuₐO (1≤a≤2) or Cu₄O₃, and dissimilar material bonding portion 5b is a portion where CuₐO or Cu₄O₃ and copper are bonded by an interatomic force or the like. Note that bonding strength between metal bump 4 and second electrode pad 7 via dissimilar material bonding portion 5b is very small as compared with bonding strength between metal bump 4 and second electrode pad 7 via metal bonding portion 4a.

On the other hand, as illustrated in FIGS. 4 to 6, metal bump 4 may be bonded to second electrode pad 7 in a state of protruding from the surface of second electrode pad 7. For example, in a case where the misalignment occurs at the time of mounting first member U1 and second member U2, metal bump 4 and second electrode pad 7 may be bonded in a mode illustrated in FIGS. 4 to 6. In addition, when first electrode pad 2 and second electrode pad 7 are arranged at a narrow pitch, when a large warp occurs in mount board 6, or the like, an amount of misalignment between metal bump 4 and second electrode pad 7 tends to increase.

When the above-described misalignment occurs, as illustrated in FIG. 6, the above-described metal bonding portion 4a and dissimilar material bonding portion 5b are formed on the bonding surface between metal bump 4 and second electrode pad 7. On the other hand, a contact surface between metal bump 4 and second insulating layer 8 is a bonding surface between a metal material and an inorganic material, and the bonding strength is extremely weak. That is, it can be said that the contact surface is a non-bonding portion 4b.

On the other hand, oxide film bonding portion 5a is formed on a contact surface between oxide film 5 and second insulating layer 8. At oxide film bonding portion 5a, oxide film 5 and second insulating layer 8 are in a state of being covalently bonded via oxygen. That is, oxide film bonding portion 5a is a portion where oxide film 5 and second insulating layer 8 are bonded by a covalent bond via oxygen. Note that the above-described voids are also formed in oxide film bonding portion 5a depending on surface roughness of metal bump 4 and second insulating layer 8.

### Method for Manufacturing Mounting Structure

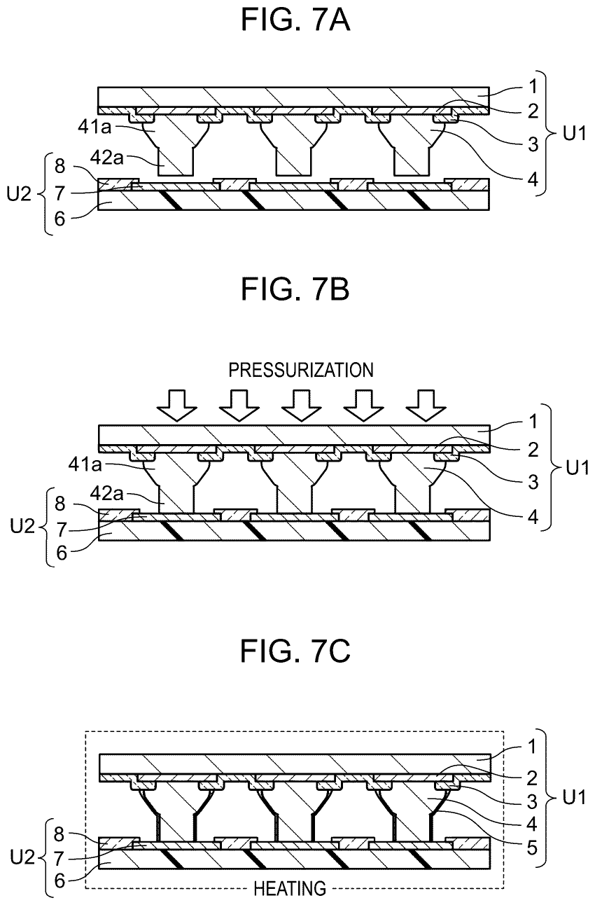

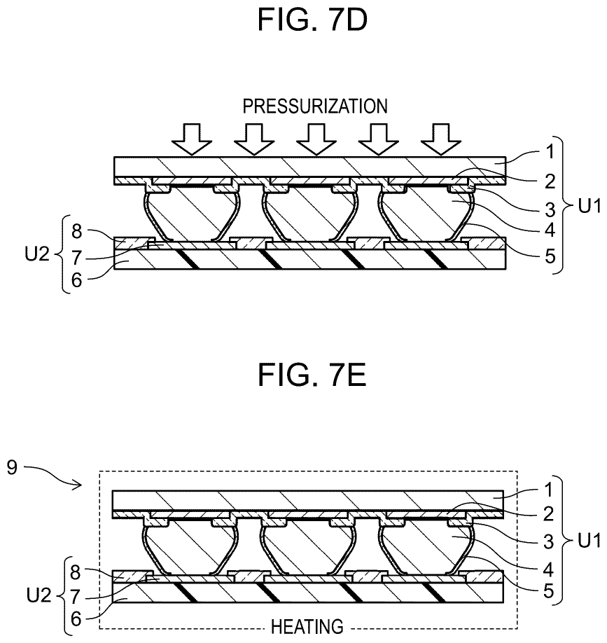

FIG. 7A is a schematic sectional view for explaining the method for manufacturing the mounting structure according to the first embodiment. FIG. 7B is a schematic sectional view for explaining a step subsequent to FIG. 7A. FIG. 7C is a schematic sectional view for explaining a step subsequent to FIG. 7B. FIG. 7D is a schematic sectional view for explaining a step subsequent to FIG. 7C. FIG. 7E is a schematic sectional view for explaining a step subsequent to FIG. 7D.

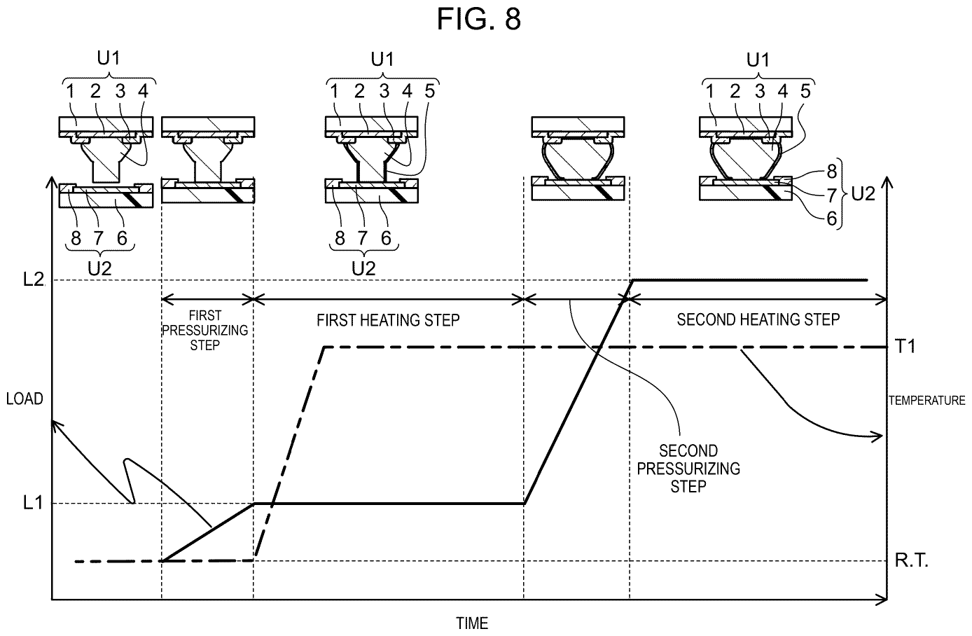

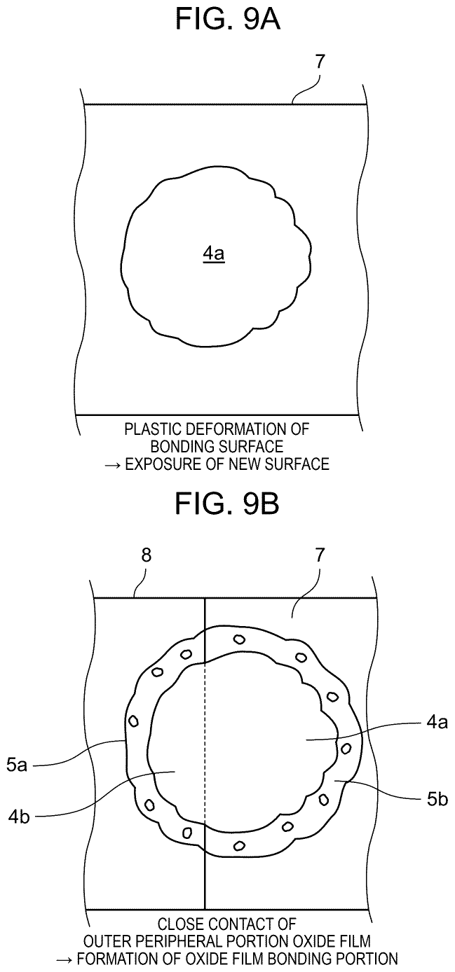

FIG. 8 is a diagram illustrating an example of temporal changes in temperature and load applied to the mounting structure in a manufacturing process. FIG. 9A is a schematic plan view of the bonding surface between the metal bump and the electrode pad while performing a first pressurizing step. FIG. 9B is a schematic plan view of the bonding surface between the metal bump and the electrode pad while performing a second pressurizing step.

First, metal bump 4 is formed on the surface of first electrode pad 2. Metal bump 4 is formed on the surface of first electrode pad 2 by, for example, a stud bump bonding method, a semi-additive method by plating, a full additive method, or the like. The shape of metal bump 4 at this time point is a substantially trapezoidal shape in which a width of bottom portion 41a is narrowed toward second member U2 in a sectional view, and tip end 42a is a rectangle extending toward second member U2 with the same width as a tip end of bottom portion 41a. In the present embodiment, a diameter of bottom portion 41a on a side close to first electrode pad 2 is 5.5 μm, and a diameter of tip end 42 a is 2.5 μm. However, the shape and dimension of metal bump 4 are not particularly limited thereto, and are appropriately changed according to a size and the like of first electrode pad 2.

As illustrated in FIG. 7A, first member U1 is disposed with respect to second member U2 such that a surface provided with first electrode pad 2 faces a surface provided with second electrode pad 7 in second member U2. At this time, first member U1 is aligned with second member U2 such that first electrode pad 2 provided with metal bump 4 and second electrode pad 7 overlap with each other with a deviation equal to or less than an allowable tolerance.

Note that in the present embodiment, the number of first electrode pads 2 provided with metal bumps 4 is 2800, but is not particularly limited thereto.

Next, as illustrated in FIG. 7B, tip end 42a of metal bump 4 is brought into contact with second electrode pad 7 from above to pressurize first member U1 downward toward second member U2 (first pressurizing step).

As illustrated in FIG. 8, the first pressurizing step is performed at room temperature (R.T.). Further, load L1 applied to second member U2 in the first pressurizing step is 4 N. While the first pressurizing step is performed, as illustrated in FIG. 9A, since metal bump 4 and second electrode pad 7 are plastically deformed at a contact portion between metal bump 4 and second electrode pad 7, a new surface is exposed, and metal bump 4 and second electrode pad 7 are bonded to each other. That is, metal bonding portion 4a is formed on the bonding surface between metal bump 4 and second electrode pad 7.

Next, as illustrated in FIG. 7C, first member U1 and second member U2 are heated in a state where metal bump 4 and second electrode pad 7 are bonded to each other (first heating step). As illustrated in FIG. 8, while the first heating step is performed, the same load (=4 N) as in the first pressurizing step is applied to second member U2. Further, in the first heating step, the temperature is rapidly raised to target temperature T1 at a temperature rising rate of 20° C./sec or higher by a rapid heating method. Note that target temperature T1 needs to be set to be equal to or lower than a heat-resistant temperature of semiconductor device 1. For example, when the heat-resistant temperature is 200° C., target temperature T1 is set to 200° C. or lower. Thus, a bonding area between metal bump 4 and second electrode pad 7, that is, a bonding area of metal bonding portion 4a can be increased by deformation of metal bump 4 due to heating. In addition, the bonding surface between metal bump 4 and second electrode pad 7 can be brought into close contact in a short time, and oxidation of the bonding surface can be suppressed. Note that target temperature T1 may be any temperature higher than room temperature.

After the temperature is raised to target temperature T1, heating atmosphere is changed to an oxidizing atmosphere in order to promote oxidation of the surface of metal bump 4. The heating atmosphere may be, for example, in a state of containing water vapor with a humidity of 60% or more. Alternatively, the heating atmosphere may be an atmosphere having a higher oxygen concentration than the atmosphere. After the heating atmosphere is changed to the oxidizing atmosphere, first member U1 and second member U2 are heated for a certain period of time, so that the oxidation of the surface of metal bump 4 can proceed to obtain oxide film 5 having a desired thickness.

Next, as illustrated in FIGS. 7D and 8, the load applied to second member U2 is increased from L1 to L2 (second pressurizing step). In the present embodiment, load L2 is 32 N.

In the second pressurizing step, metal bump 4 is further deformed by applying a load higher than that in the first pressurizing step. At that time, oxide film 5 formed at a tip end of metal bump 4 in the first heating step comes into close contact with second electrode pad 7 while being plastically deformed. At this time, as illustrated in FIG. 9B, the above-described dissimilar material bonding portion 5b is formed at a portion in contact with oxide film 5 and second electrode pad 7, and the above-described oxide film bonding portion 5a is formed at a portion in contact with oxide film 5 and second insulating layer 8.

After the second pressurizing step is performed, first member U1 and second member U2 are heated for a certain period of time as they are (second heating step illustrated in FIGS. 7E and 8). In this way, a solid phase reaction proceeds on the bonding surface between metal bump 4 and second electrode pad 7, and metal bonding portion 4a grows to be strong. In addition, a contact surface between oxide film 5 and second electrode pad 7 has bondability by the covalent bond via oxygen.

In the second heating step, as illustrated in FIG. 8, the same load (=32 N) as that applied in the second pressurizing step is applied to second member U2. In this way, the solid phase reaction further proceeds on the bonding surface between metal bump 4 and second electrode pad 7. In addition, the bondability due to the covalent bond via oxygen is improved on the contact surface between oxide film 5 and second electrode pad 7. However, in the second heating step, a load smaller than that in the second pressurizing step may be applied to second member U2.

### Effects and the Like

As described above, mounting structure 9 according to the present embodiment includes first member U1 and second member U2 disposed to face first member U1. First member U1 includes at least semiconductor device 1, first electrode pad 2 formed on semiconductor device 1, and metal bump 4 formed on the surface of first electrode pad 2. Second member U2 includes at least mount board 6, second electrode pad 7 formed on mount board 6 and bonded to metal bump 4, and second insulating layer 8.

Oxide film 5 is formed on the surface of metal bump 4.

Metal bonding portion 4a is formed between metal bump 4 and second electrode pad 7, wherein at metal bonding portion 4a, metal constituting metal bump 4 and metal constituting second electrode pad 7 are metal-bonded.

Oxide film bonding portion 5a is formed between oxide film 5 and second insulating layer 8, wherein at oxide film bonding portion 5a, oxide film 5 and second insulating layer 8 are bonded.

Further, oxide film 5 and second insulating layer 8 are bonded by the covalent bond via oxygen at oxide film bonding portion 5a.

According to the present embodiment, even when first member U1 and second member U2 are mounted in a state where metal bump 4 protrudes from second electrode pad 7 due to misalignment at the time of mounting, oxide film 5 and second insulating layer 8 are bonded to form oxide film bonding portion 5a. Since oxide film 5 and second insulating layer 8 are bonded by the covalent bond at oxide film bonding portion 5a, oxide film bonding portion 5a has a predetermined bonding strength.

These factors make it possible to increase the tolerance of misalignment at the time of mounting in mounting structure 9. In addition, the bonding strength between first member U1 and second member U2 can be secured. As a result, connection reliability between first member U1 and second member U2, specifically, connection reliability between metal bump 4 and second electrode pad 7 can be enhanced.

Each of materials of first electrode pad 2 and second electrode pad 7 is preferably selected from a group consisting of gold, copper, aluminum, an alloy of aluminum and copper, and tungsten.

A material of metal bump 4 is preferably selected from a group consisting of copper, aluminum, titanium, and tungsten. Note that any of first electrode pad 2, second electrode pad 7, and metal bump 4 may contain a small amount of one or more types of impurities, for example, inevitable impurities mixed in the manufacturing process.

In particular, when metal bump 4 is made of metal such as copper or aluminum which is easily deformed by pressurization, since tip end 42 is deformed in the second pressurizing step, the bonding area between metal bump 4 and second electrode pad 7 increases, and the bonding strength between first member U1 and second member U2 can be increased. Further, the connection reliability between first member U1 and second member U2 can be enhanced.

In addition, in a case where metal bump 4 and second electrode pad 7 are made of the same kind of metal, an intermetallic compound or the like is not generated, so that bonding strength of metal bonding portion 4a, and therefore the bonding strength between first member U1 and second member U2 can be increased. Further, the connection reliability between first member U1 and second member U2 can be enhanced.

A material of second insulating layer 8 preferably includes at least one of silicon oxide and silicon nitride. This allows the covalent bond via oxygen to be easily generated with oxide film 5.

Metal bump 4 may have bottom portion 41 in contact with the surface of first electrode pad 2 and tip end 42 protruding from bottom portion 41. In that case, the diameter of bottom portion 41 is preferably larger than that of tip end 42. In this way, when first member U1 is mounted on second member U2, a pressure applied to second electrode pad 7 can be increased, and an oxide film formed on surfaces of oxide film 5 and second electrode pad 7 is easily broken at the portion where metal bump 4 and second electrode pad 7 are in contact with each other. Thus, metal bonding portion 4a is easily formed by pressurization and heating at the time of mounting, and the bonding area can be increased. As a result, the bonding strength between first member U1 and second member U2 can be increased. Further, the connection reliability between first member U1 and second member U2 can be enhanced.

The method for manufacturing mounting structure 9 according to the present embodiment includes at least a plurality of steps described below.

In the first pressurizing step, load L1 is applied between first member U1 and second member U2 in a state where first member U1 and second member U2 face each other, to form metal bonding portion 4a between metal bump 4 and second electrode pad 7.

In the first heating step, first member U1 and second member U2 are heated after performing the first pressurizing step, to increase the bonding area of metal bonding portion 4a.

In the second pressurizing step, load L2 higher than that in the first pressurizing step is applied between first member U1 and second member U2. Further, in the second pressurizing step, the oxide film bonding portion 5a is formed between oxide film 5 and second insulating layer 8.

According to the present embodiment, even when first member U1 and second member U2 are mounted in a state where metal bump 4 protrudes from second electrode pad 7 due to misalignment at the time of mounting, metal bonding portion 4a is formed at the portion where metal bump 4 and second electrode pad 7 are in contact with each other. Further, oxide film bonding portion 5a is formed at the portion where oxide film 5 and second insulating layer 8 are in contact with each other.

These factors make it possible to increase the tolerance of misalignment at the time of mounting in mounting structure 9. In addition, the bonding strength between first member U1 and second member U2 can be secured. Further, the connection reliability between first member U1 and second member U2 can be enhanced.

In the first heating step, oxide film 5 is preferably formed on the surface of metal bump 4 by further heating first member U1 and second member U2 under the oxidizing atmosphere. In this way, oxide film 5 having a desired thickness can be formed on the surface of metal bump 4. Thus, in the second pressurizing step, the oxide film bonding portion 5a can be formed at the portion where oxide film 5 and second insulating layer 8 are in contact with each other, and the bonding strength between first member U1 and second member U2 can be secured.

It is preferable to further include the second heating step of heating first member U1 and second member U2 at temperature T1 higher than that in the first heating step after the second pressurizing step is performed. In this way, the solid phase reaction proceeds on the bonding surface between metal bump 4 and second electrode pad 7, and metal bonding portion 4a can be strong. In addition, the bondability due to the covalent bond via oxygen is improved on the contact surface between oxide film 5 and second electrode pad 7, and oxide film bonding portion 5a can be strong. These factors make it possible to increase the bonding strength between first member U1 and second member U2. Further, the connection reliability between first member U1 and second member U2 can be enhanced.

Note that it is preferable to further include a plasma treatment step of reducing the oxide film formed each on surfaces of metal bump 4 and second electrode pad 7 by plasma treatment, before performing the first pressurizing step. In this way, in the first pressurizing step, the new surface can be easily exposed at the portion where metal bump 4 and second electrode pad 7 are in contact with each other, and metal bonding portion 4a can be reliably formed.

In the first heating step, oxide film 5 is preferably grown on the surface of metal bump 4 by the rapid heating method. In this way, the bonding surface between metal bump 4 and second electrode pad 7 can be brought into close contact in a short time, and the oxidation of the bonding surface can be suppressed.

The first heating step and the second pressurizing step may be performed simultaneously. In this way, process time can be shortened, and manufacturing cost of mounting structure 9 can be reduced. Similarly, the second pressurizing step and the second heating step may be performed simultaneously. In this way, process time can be shortened, and manufacturing cost of mounting structure 9 can be reduced.

### Second Embodiment

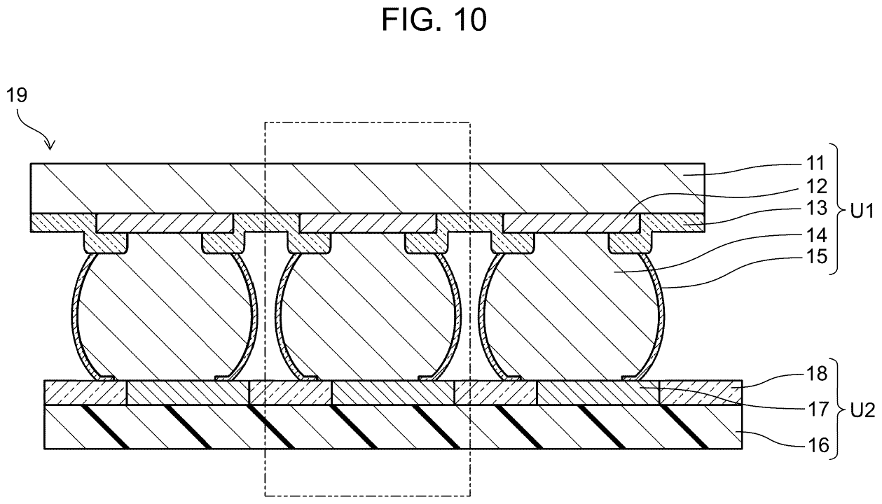

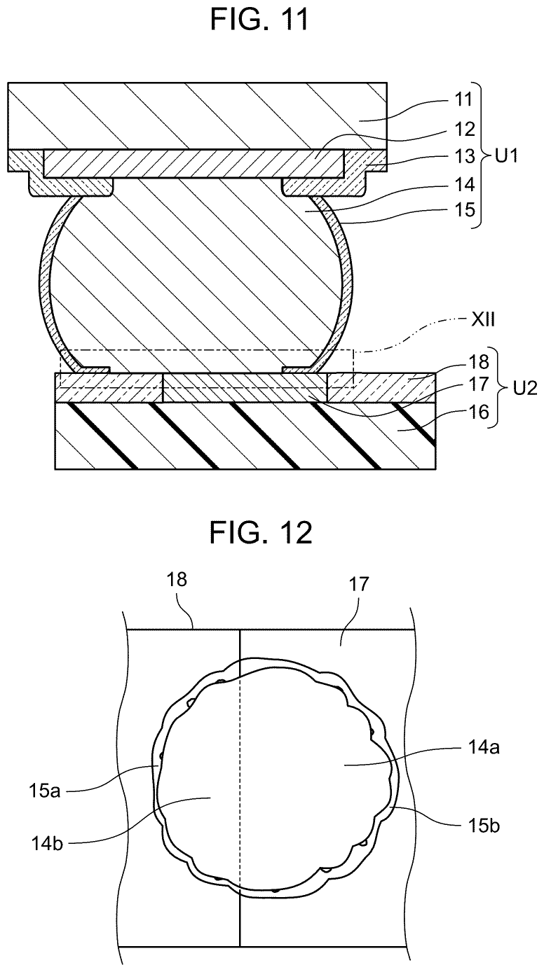

FIG. 10 is a schematic sectional view of the second main part of the mounting structure according to a second embodiment. FIG. 11 is an enlarged view of a part of the mounting structure illustrated in FIG. 10. FIG. 12 is a schematic plan view of the bonding surface between the metal bump and the electrode pad in the mounting structure illustrated in FIG. 11.

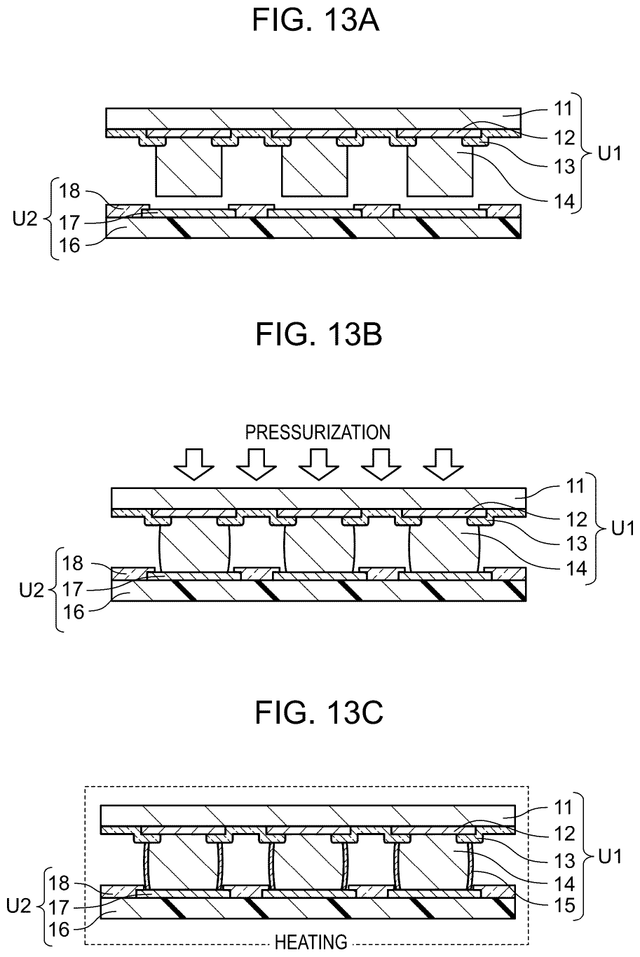

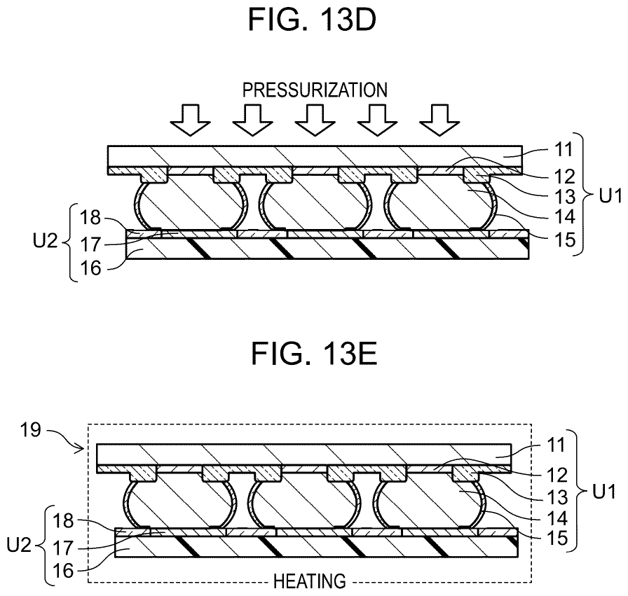

FIG. 13A is a schematic sectional view for explaining the method for manufacturing the mounting structure according to the second embodiment. FIG. 13B is a schematic sectional view for explaining a step subsequent to FIG. 13 A. FIG. 13C is a schematic sectional view for explaining a step subsequent to FIG. 13B. FIG. 13D is a schematic sectional view for explaining a step subsequent to FIG. 13C. FIG. 13E is a schematic sectional view for explaining a step subsequent to FIG. 13D.

FIGS. 10 to 12 shown in the present embodiment correspond to FIGS. 4 to 6 shown in the first embodiment, and FIGS. 13A to 13E correspond to FIGS. 7A to 7E. Further, members and portions indicated by reference numerals 1 to 9 in FIGS. 4 to 7E are indicated by reference numerals 11 to 19 in FIGS. 10 to 13E.

In mounting structure 19 of the present embodiment illustrated in FIGS. 10 to 13E, metal bump 14 is different from metal bump 4 shown in the first embodiment in that metal bump 14 has a columnar pillar shape, and the other components are the same as those of the first embodiment. Therefore, detailed description of FIGS. 10 to 13E will be omitted.

In a case where metal bump 14 is made of, for example, a metal such as tungsten which is hardly deformed by pressurization and heating, and has tip end 42a having a small diameter like metal bump 4, a bonding area between metal bump 14 and second electrode pad 17 may be rather reduced. In such a case, as shown in the present embodiment, the shape of metal bump 4 may be columnar to secure the bonding area between metal bump 14 and second electrode pad 17. Note that the shape of metal bump 14 is not limited to a column, and may be, for example, a polygonal column.

### Other Embodiments

Target temperature T1, the temperature rising rate, and the load described above are not particularly limited to examples disclosed in the present specification. They are appropriately set according to the size, shape, material, and the like of metal bump 4 and second electrode pad 7.

In addition, the shape of metal bump 4 shown in the first embodiment may be applied to that of metal bump 14 shown in the second embodiment. In this way, in the first pressurizing step, the oxide film formed on surfaces of oxide film 15 and second electrode pad 17 is easily broken, and a new surface is reliably formed at a portion where metal bump 14 and second electrode pad 17 are in contact with each other. As a result, metal bonding portion 14a can be easily formed.

In addition, the shape of metal bump 14 shown in the second embodiment may be applied to that of metal bump 4 shown in the first embodiment. In this way, an area of the tip end of metal bump 4 can be increased. Thus, the bonding area between metal bump 4 and second electrode pad 7 and a bonding area between oxide film 5 and second insulating layer 8 can be increased, and the bonding strength between first member U1 and second member U2 can be increased.

Further, among members constituting first member U1, semiconductor device 1 may be another member, for example, the mount board such as the circuit board or the wiring board.

According to the present disclosure, in the mounting structure of the first member provided with the bump and the second member provided with the electrode pad, it is possible to increase the tolerance of misalignment at the time of mounting. In addition, the bonding strength between the first member and the second member can be secured.

The mounting structure of the present disclosure is useful because it is possible to increase the tolerance of misalignment when the first member and the second member are mounted, and to secure the bonding strength between the first member and the second member.

What is claimed is:

1. A mounting structure comprising:
a first member including a first electrode pad and a metal bump disposed on a surface of the first electrode pad; and
a second member disposed to face the first member and including a second electrode pad bonded to the metal bump, and a second insulating layer,
wherein an oxide film is formed on a surface of the metal bump,
a metal bonding portion is formed between the metal bump and the second electrode pad, wherein at the metal bonding portion, metal constituting the metal bump and metal constituting the second electrode pad are metal-bonded, and
an oxide film bonding portion is formed between the oxide film and the second insulating layer, wherein at the oxide film bonding portion, the oxide film and the second insulating layer are bonded.

2. The mounting structure according to claim 1, wherein a dissimilar material bonding portion is formed between the oxide film and the second electrode pad, wherein at the dissimilar material bonding portion, the oxide film and the second electrode pad are bonded.

3. The mounting structure according to claim 1, wherein each of materials of the first electrode pad and the second electrode pad is made of a material selected from a group consisting of gold, copper, aluminum, an alloy of aluminum and copper, and tungsten.

4. The mounting structure according to claim 1, wherein a material of the metal bump is made of a material selected from a group consisting of copper, aluminum, titanium, and tungsten.

5. The mounting structure according to claim 1, wherein a material of the second insulating layer includes at least one of silicon oxide and silicon nitride.

6. The mounting structure according to claim 1, wherein at the oxide film bonding portion, the oxide film and the second insulating layer are bonded by covalent bonding via oxygen.

7. The mounting structure according to claim 1, wherein
the metal bump includes:
a bottom portion in contact with the surface of the first electrode pad; and
a tip end protruding from the bottom portion, and
a diameter of the bottom portion is larger than a diameter of the tip end.

8. A method for manufacturing the mounting structure according to claim 1 comprising:
a first pressurizing step of applying a load between the first member and the second member in a state where the first member and the second member face each other, to form the metal bonding portion between the metal bump and the second electrode pad;
a first heating step of heating the first member and the second member after performing the first pressurizing step, to increase a bonding area of the metal bonding portion; and
a second pressurizing step of applying a load higher than the load in the first pressurizing step between the first member and the second member, to form the oxide film bonding portion at least between the oxide film and the second insulating layer.

9. The method for manufacturing the mounting structure according to claim 8, wherein in the first heating step, the oxide film is formed on the surface of the metal bump by further heating the first member and the second member in an oxidizing atmosphere.

10. The method for manufacturing the mounting structure according to claim 8, further comprising a plasma treatment step of reducing the oxide film formed on each of surfaces of the metal bump and the second electrode pad by plasma treatment, before performing the first pressurizing step.

11. The method for manufacturing the mounting structure according to claim 8, wherein the first heating step and the second pressurizing step are performed simultaneously.

12. The method for manufacturing the mounting structure according to claim 8, wherein in the first heating step, the oxide film is grown on the surface of the metal bump by a rapid heating method.

13. The method for manufacturing the mounting structure according to claim 8, further comprising a second heating step of heating the first member and the second member at a higher temperature than a temperature in the first heating step, after the second pressurizing step.
